(19) United States
(12) Patent Application Publication
(10) Pub. No.: US 2007/0215933 A1
(43) Pub. Date: Sep. 20, 2007

(54) SEMICONDUCTOR DEVICE

(75) Inventor: Takashi YUDA, Kanagawa (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/676,512

(22) Filed: Feb. 20, 2007

(30) Foreign Application Priority Data
Mar. 14, 2006 (JP) 2006-068678

(51) Int. Cl. H01L 29/788

(52) U.S. Cl. 257/315

(57) ABSTRACT

It is an object of the present invention to provide a semiconductor device that enables cost increase to be inhibited and enables cell size to be reduced, and a method for manufacturing the same. A semiconductor device includes a semiconductor substrate, a gate electrode, a first sidewall, and a second sidewall. The gate electrode is formed above the semiconductor substrate. The first sidewall is formed above the semiconductor substrate to be adjacent to the gate electrode. The second sidewall is formed above the semiconductor substrate to face the first sidewall across the gate electrode. The first sidewall includes a first sloping surface. The first sloping surface faces the gate electrode. The first sloping surface slopes so as to close the gap with a second sidewall as it gets closer to the semiconductor substrate. The first sidewall includes a second sloping surface. The second sloping surface faces the gate electrode. The second sloping surface slopes to be closed to the first sidewall as it gets closer to the semiconductor substrate. The gate electrode is formed to include a surface located along the first sloping surface and a surface located along the second sloping surface.

### CROSS-REFERENCE TO RELATED APPLICATIONS

This application claims priority to Japanese Patent Application No. 2006-068678. The entire disclosure of Japanese Patent Application No. 2006-068678 is hereby incorporated herein by reference.

### BACKGROUND OF THE INVENTION

1. Field of the Invention

The present invention relates to a semiconductor device and a method for manufacturing the same.

2. Background Information

A semiconductor device has been proposed in the past that includes a gate electrode and two sidewalls located on both sides thereof to face with each other (e.g., see Japan Patent Application Publication JP-A-2003-332474 (pages 1 to 19, and FIGS. 1 to 21)).

In the art described in Japan Patent Application Publication JP-A-2003-332474, a gate electrode is formed to have an approximately rectangular shape in a cross section that is perpendicular to a longitudinal direction, and two sidewalls are formed thereafter. Because of this, lateral sides of the gate electrode tend to be formed to extend in a direction that is perpendicular to a semiconductor substrate. Accordingly, it may be difficult to reduce the gate length more than a gate length to be reduced by conventional exposure equipment. Therefore, it may be difficult to reduce the cell size.

On the other hand, the cell size may be reduced if higher-performance equipment are used instead of the conventional exposure equipment. However, overall costs may be increased thereby.

In view of the above, it will be apparent to those skilled in the art from this disclosure that there exists a need for an improved semiconductor device by which cost increase is inhibited and cell size is reduced and an improved method for manufacturing the same. This invention addresses this need in the art as well as other needs, which will become apparent to those skilled in the art from this disclosure.

### SUMMARY OF THE INVENTION

According to a first aspect of the present invention, a semiconductor device includes a semiconductor substrate, a gate electrode, a first sidewall, and a second sidewall. The gate electrode is disposed above the semiconductor device. The first sidewall is disposed above the semiconductor substrate to be adjacent to the gate electrode. The second sidewall is disposed above the semiconductor substrate to face the first sidewall across the gate electrode. The first sidewall includes a first sloping surface. The first sloping surface faces the gate electrode. The first sloping surface slopes so as to close the gap with the second sidewall as it gets closer to the semiconductor substrate. The second sidewall includes a second sloping surface. The second sloping surface faces the gate electrode. The second sloping surface slopes so as to close the gap with the first sidewall as it gets closer to the semiconductor substrate. The gate electrode is formed to include a surface disposed along the first sloping surface and a surface disposed along the second sloping surface.

According to the semiconductor device, the gate electrode is formed to include the surface along the first sloping surface and the surface along the second sloping surface. Because of this, it is possible to further reduce a gate length reduced by conventional exposure equipment.

As described above, it is possible to further reduce the gate length reduced by conventional exposure equipment. Therefore, it enables cost increase to be inhibited and enables the cell size to be reduced.

According to a second aspect of the present invention, a method for manufacturing a semiconductor device includes the steps of preparing a semiconductor substrate, forming a first sidewall and a second sidewall, and forming a gate electrode. In preparing the semiconductor substrate, a semiconductor substrate is prepared. In forming a first sidewall and a second sidewall, first and second sidewalls are formed to be arranged side by side above a semiconductor substrate. In forming a gate electrode, a gate electrode is formed to be disposed between the first and second sidewalls after forming the first and second sidewalls. In forming the first and second sidewalls, a first sloping surface and a second sloping surface are also formed. The first sloping surface faces the gate electrode above the first sidewall and slopes so as to close the gap with the second sidewall as it gets closer to the semiconductor substrate. The second sloping surface faces the gate electrode above the second sidewall and slopes so as to close the gap with the first sidewall as it gets closer to the semiconductor substrate. In forming the gate electrode, the gate electrode is formed to include a surface disposed along the first sloping surface and a surface disposed along the second sloping surface.

According to the method for manufacturing a semiconductor device, in forming the gate electrode, the gate electrode is formed to include the surface disposed along the first sloping surface and the surface disposed along the second sloping surface. Therefore, this enables the gate electrode to be formed such that the gate length thereof reduced by conventional exposure equipment can be further reduced.

As described above, the gate electrode can be formed such that the gate length thereof reduced by conventional exposure equipment can be further reduced. Therefore, cost increase can be inhibited and the cell size can be reduced.

As described above, according to the semiconductor device in accordance with the present invention, it is possible to further reduce the gate length reduced by conventional exposure equipment. Therefore, cost increase can be inhibited and the cell size can be reduced.

In addition, as described above, according to the method for manufacturing a semiconductor device, the gate electrode can be formed such that the gate length thereof reduced by conventional exposure equipment can be further reduced. Therefore, cost increase can be inhibited and the cell size can be reduced.

According to a third aspect of the present invention, the method for manufacturing a semiconductor device according to the second aspect of the present invention includes the steps of forming a first insulation layer of the first sidewall and a second insulation layer of the second sidewall in forming the first sidewall and the second sidewall, and forming a first charge storage layer configured to store charges above the first insulation layer and a second charge storage layer configured to store charges above the second insulation layer in forming the first sidewall and the second sidewall.

According to a fourth aspect of the present invention, the method for manufacturing a semiconductor device according to the third aspect of the present invention includes a step of forming a third insulation layer to be disposed above the first charge storage layer and a fourth insulation layer to be disposed above the second charge storage layer. Here, the third insulation layer includes the first sloping surface, and the fourth insulation layer includes the second sloping surface.

According to a fifth aspect of the present invention, the method for manufacturing a semiconductor device according to the second aspect of the present invention includes a step of forming a first diffusion region by implanting first ions into the semiconductor substrate in preparing the semiconductor substrate, and further includes a step of partially separating the first diffusion region by implanting second ions into a portion of the first diffusion region with use of the first sidewall and the second sidewall as masks after forming the first sidewall and the second sidewall and before forming the gate electrode. Here, the second ions have opposite polarity from that of the first ions.

According to a sixth aspect of the present invention, the method for manufacturing a semiconductor device according to the second aspect of the present invention further includes the steps of forming a wiring layer above the gate electrode, forming a hardmask layer above the wiring layer, patterning the hardmask layer, and patterning the wiring layer with use of the patterned hardmask layer as a mask and at the same time as this etching portions of the gate electrode not covered with the wiring layer.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure.

FIG. 1 is a layout of a semiconductor device of the present invention.

FIG. 2 is a cross-sectional view in a cross section II-II of the semiconductor device shown in FIG. 1.

FIG. 3 is a cross-sectional view in a cross section III-III of the semiconductor device shown in FIG. 1.

FIGS. 4A to 4C are cross-sectional views showing a method configured to manufacture the semiconductor device.

FIGS. 5A to 5D are cross-sectional views showing the method configured to manufacture the semiconductor device.

FIG. 6 is a layout of a semiconductor device in accordance with a first embodiment of the present invention.

FIG. 7 is a cross-sectional view in a cross section VII-VII of the semiconductor device in accordance with the first embodiment shown in FIG. 6.

FIG. 8 is a cross-sectional view in a cross section VIII-VIII of the semiconductor device in accordance with the first embodiment shown in FIG. 6.

FIGS. 9A to 9D are cross-sectional views showing a method configured to manufacture the semiconductor device in accordance with the first embodiment.

FIGS. 10A to 10C are cross-sectional views showing the method configured to manufacture the semiconductor device in accordance with the first embodiment.

FIG. 11 is a layout of a semiconductor device in accordance with a second embodiment of the present invention.

FIG. 12 is a cross-sectional view in a cross section XII-XII of the semiconductor device in accordance with the second embodiment shown in FIG. 11.

FIG. 13 is a cross-sectional view in a cross section XIII-XIII of the semiconductor device in accordance with the second embodiment shown in FIG. 11.

FIG. 14 is a cross-sectional view in a cross section XIV-XIV of the semiconductor device in accordance with the second embodiment shown in FIG. 11.

FIG. 15 is a cross-sectional perspective view showing the method configured to manufacture the semiconductor device in accordance with the second embodiment.

FIGS. 16A and 16B are cross-sectional views showing the method configured to manufacture the semiconductor device in accordance with the second embodiment.

FIGS. 17A to 17C are cross-sectional views showing the method configured to manufacture the semiconductor device in accordance with the second embodiment.

### DETAILED DESCRIPTION OF THE PREFERRED EMBODIMENTS

Selected embodiments of the present invention will now be explained with reference to the drawings. It will be apparent to those skilled in the art this disclosure that the following descriptions of the embodiments of the present invention are provided for illustration only and for the purpose of limiting the invention as defined by the appended claims and their equivalents.

### Semiconductor Device of the Present Invention

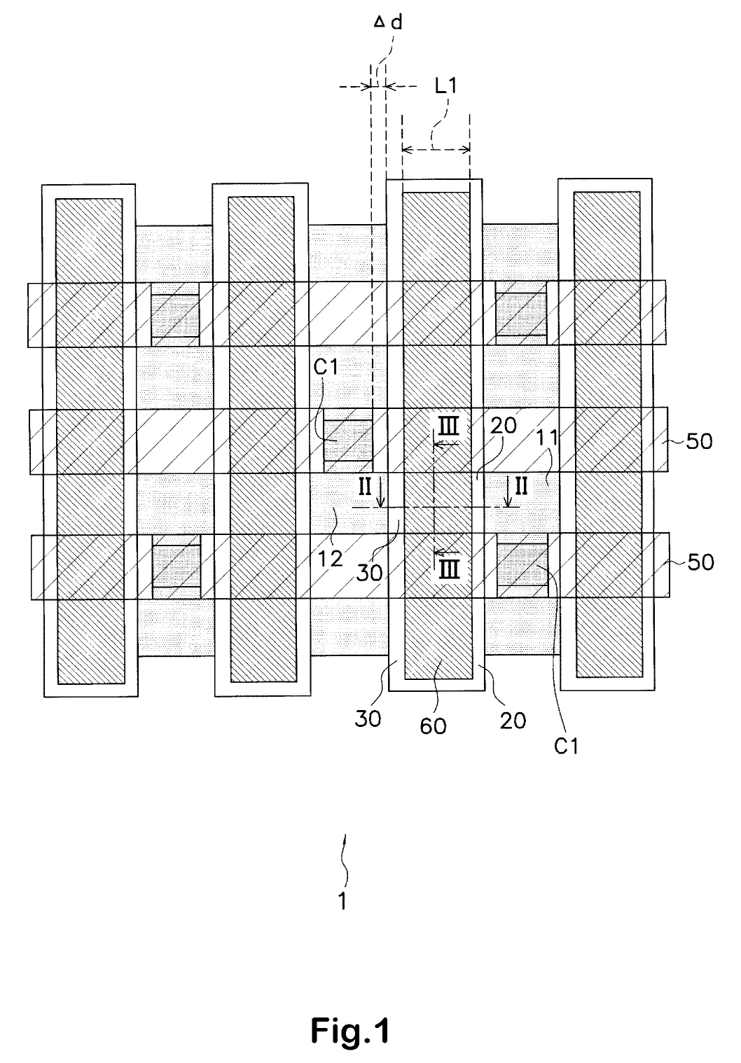

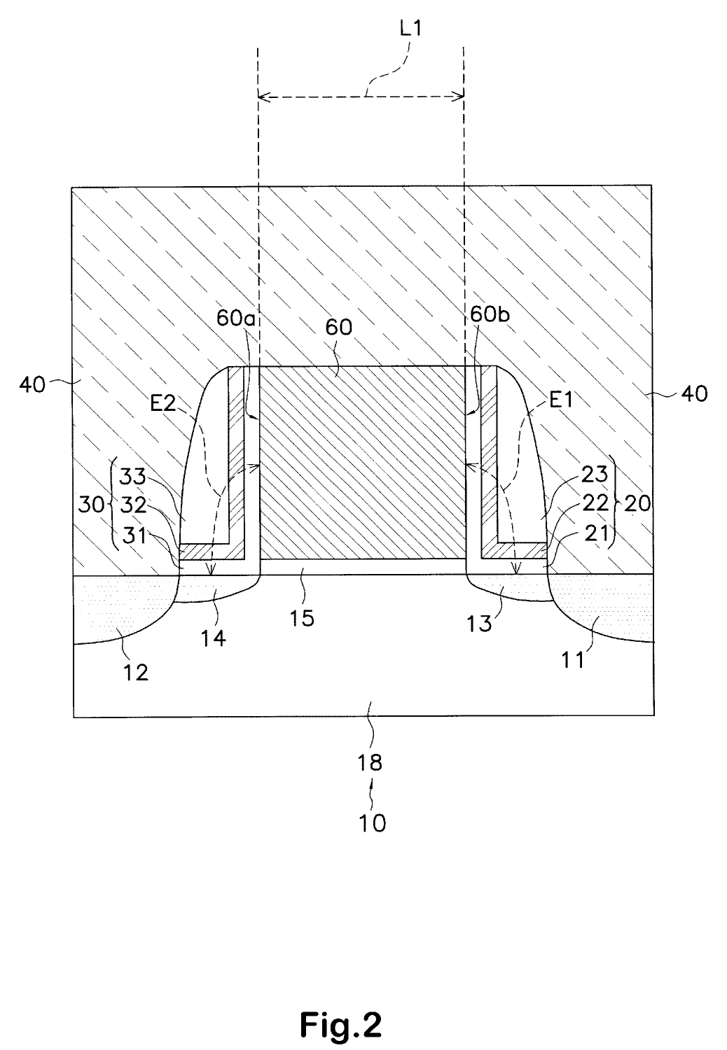

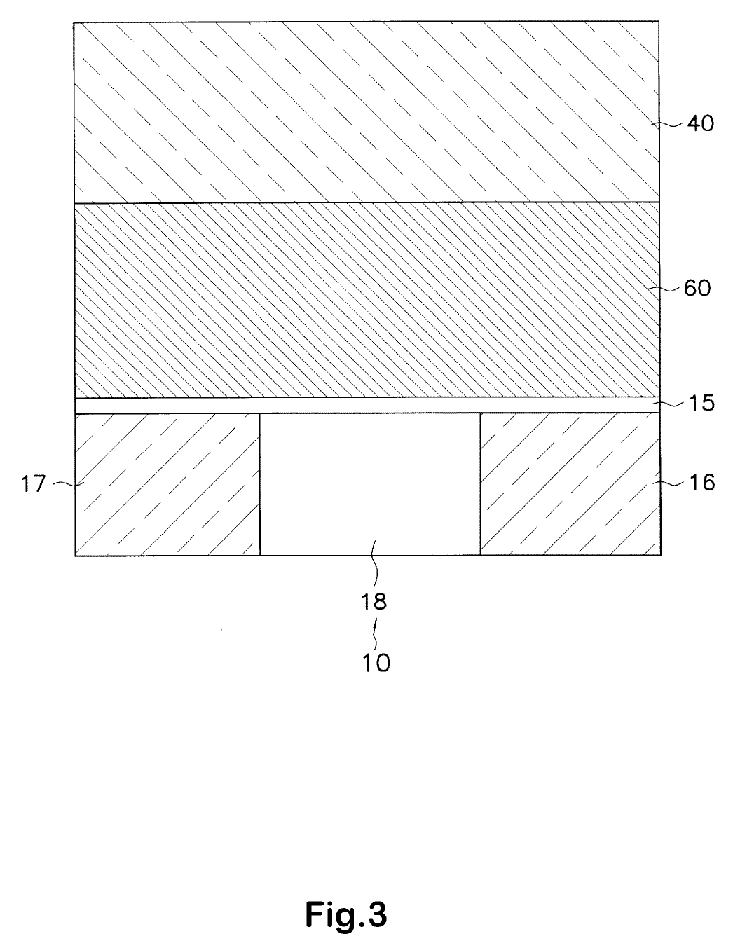

FIG. 1 is a layout of a semiconductor device of the present invention. FIG. 2 is a cross-sectional view in a cross section II-II of the semiconductor device shown in FIG. 1. FIG. 3 is a cross-sectional view in a cross section III-III of the semiconductor device shown in FIG. 1.

### Overall Configuration and Operation of Semiconductor Device

A semiconductor device 1 has a nonvolataile memory function, and chiefly includes a semiconductor substrate 10 (see FIG. 2), a gate electrode 60, a first sidewall 20, a second sidewall 30, an interlayer film 40 (see FIG. 2), and a wiring layer 50.

Element isolation films 16 and 17 (see FIG. 3) and diffusion layers 11 and 12 are formed in the semiconductor substrate 10. The element isolation films 16 and 17 delimit an active region and a non-active region on the surface of the semiconductor substrate 10. More specifically, a region in which the element isolation films 16 and 17 are formed is delimited as the non-active region. On the other hand, a region in which the element isolation films 16 and 17 are not formed is delimited as the active region. The diffusion layers 11 and 12 are formed in a portion of the active region, respectively, and function as either a source electrode or a drain electrode of a memory cell (i.e., transistor), respectively.

Here, the element isolation films 16 and 17 chiefly consist of a silicon oxide film. The diffusion layers 11 and 12 are regions comprised of silicon in which n-type impurities are highly doped, and the other portions of the active region excluding the diffusion layers 11 and 12 are regions comprised of silicon in which p-type impurities are lightly-doped.

The gate electrode 60 is formed to linearly extend above the semiconductor device 10. The gate electrode 60 functions not only as a gate electrode of a memory cell (i.e., transistor) but also as a word line. Thus, the gate electrode 60 is configured such that a signal configured to switch on/off the memory cell (i.e., transistor) is allowed to be input therein.

The first sidewall 20 is formed to be located immediately above the semiconductor substrate 10. More specifically, it is located in a position where it is laterally adjacent to the gate electrode 60 so that it linearly extends in parallel with the gate electrode 60. With this configuration, the first sidewall 20 is allowed to store charges by the electric field generated between the gate electrode 60 and the diffusion layer 11. In other words, it is allowed to store information. The first sidewall 20 is formed to have a multi-layer structure as described below.

The second sidewall 30 is formed to be located immediately above the semiconductor substrate 10. More specifically, it is located in a position where it faces the first sidewall 20 across the gate electrode 60 such that it linearly extends in parallel with the gate electrode 60. With this configuration, the second sidewall 20 is allowed to store charges by the electric field generated between the gate electrode 60 and the diffusion layer 12. In other words, it is allowed to store information. The second sidewall 30 is formed to have a multi-layer structure as described below.

The interlayer film 40 is formed to be located vertically between the gate electrode 60 and the wiring layer 50. Because of this, short circuit will not be caused between the gate electrode 60 and the wiring layer 50.

The wiring layer 50 is formed to be located above the gate electrode 60 through the interlayer film 40. In addition, the wiring layer 50 is formed to be located above the gate electrode 60 so that it extends in an approximately perpendicular direction to the direction in which the gate electrode 60 extends. The wiring layer 50 is coupled to the diffusion layers 11 and 12 through a plurality of contacts C1 (black portions shown in FIG. 1), and functions as a bit line. In addition, the wiring layer 50 is configured so that a signal configured to store information (i.e., charges) in the first sidewall 20 and/or the second sidewall 30 is allowed to be input into the diffusion layers 11 and 12 through the contacts C1. The wiring layer 50 chiefly consists of a metal (e.g., tungsten).

Here, it is necessary to space a predetermined space Δd or greater laterally between the contact C1, and the first sidewall 20 and/or the second sidewall 30 for the purpose of avoiding problems such as loose connection between the contact C1 and the diffusion layers 11 and 12. With this configuration, there exists a limitation to reduce the cell size by forming adjacent gate electrodes 60 to be located close to each other.

### Detailed Memory Cell Configuration

As shown in FIG. 2, a memory cell (transistor) chiefly includes the gate electrode 60, a gate insulation film 15, the first sidewall 20, the second sidewall 30, a first LDD layer 13, a second LDD layer 14, and source and drain electrodes (i.e., the diffusion layers 11 and 12).

The gate electrode 60 is formed to have an approximately rectangular shape in a cross section thereof that is perpendicular to a longitudinal direction (see FIG. 1) of the first sidewall 20. In addition, the gate electrode 60 chiefly consists of polysilicon.

The gate insulation film 15 is formed to be located between the semiconductor substrate 10 and the gate electrode 60. With this configuration, the semiconductor substrate 10 and the gate electrode 60 are configured to be electrically isolated from each other. The gate insulation film 15 includes a surface 60b that faces the first sidewall 20 and a surface 60a that faces the second sidewall 30.

The first sidewall 20 chiefly includes a first insulation layer 21, a first charge storage layer 22, and a third insulation layer 23. The first charge storage layer 22 stores charges of, for example, holes and electrons. The first insulation layer 21 is formed to be located between the semiconductor substrate 10 and the first charge storage layer 22. With this configuration, the semiconductor substrate 10 and the first charge storage layer 22 are configured to be electrically isolated from each other. The third insulation layer 23 is formed to be located to face the first insulation layer 21 across the first charge storage layer 22. With this configuration, an upper layer located on/above the first sidewall 20 and the first charge storage layer 22 are configured to be electrically isolated from each other. In other words, with the configuration in which the first charge storage layer 22 is interposed between the first insulation layer 21 and the third insulation layer 23, the first charge storage layer 22 is configured to stably retain charges of, for example, holes and electrons. Note that the first insulation layer 21 and the third insulation layer 23 are films chiefly consisting of silicon oxide, and the first charge storage layer 22 is a film chiefly consisting of silicon nitride.

The diffusion layer 11 is formed in the semiconductor substrate 10. More specifically, it is formed to be located in a position where it is adjacent to the first sidewall 20 and apart from the gate electrode 60. The diffusion layer 11 is a region in which n-type impurities are highly doped and functions as a source/drain electrode.

The first LDD layer 13 is formed in the semiconductor substrate 10. More specifically, it is formed to be located laterally between the gate electrode 60 and the diffusion layer 11 so that the thickness thereof gradually increases as the horizontal position thereof is apart from the gate electrode 60. The first LDD layer 13 is a region in which n-type impurities are lightly doped.

On the other hand, the second sidewall 30 chiefly includes a second insulation layer 31, a second charge storage layer 32, and a fourth insulation layer 33. The second charge storage layer 32 stores charges of, for example, holes and electrons. The second insulation film 31 is formed to be located between the semiconductor substrate 10 and the second charge storage layer 32. With this configuration, the semiconductor substrate 10 and the second charge storage layer 32 are configured to be electrically isolated from each other. The fourth insulation layer 33 is formed to be located to face the second insulation layer 31 across the second charge storage layer 32. With this configuration, an upper layer located on/above the second sidewall 30 and the second charge storage layer 32 are configured to be electrically isolated from each other. In other words, with the configuration in which the second charge storage layer 32 is interposed between the second insulation layer 31 and the fourth insulation layer 33, the second charge storage layer 32 is configured to stably retain charges of, for example, holes and electrons. Note that the second insulation layer 31 and the fourth insulation layer 33 are films chiefly consisting of silicon oxide, and the second charge storage layer 32 is a film chiefly consisting of silicon nitride.

The diffusion layer 12 is formed in the semiconductor substrate 10. More specifically, it is formed to be located in a position where it is adjacent to the second sidewall 30 and apart from the gate electrode 60. The diffusion layer 12 is a region in which n-type impurities are highly doped and functions as a source/drain electrode.

The second LDD layer 14 is formed in the semiconductor substrate 10. More specifically, it is formed to be located laterally between the gate electrode 60 and the diffusion layer 12 so that thickness thereof gradually increases as the horizontal position thereof is apart from the gate electrode 60. The second LDD layer 14 is a region in which n-type impurities are lightly doped.

Here, it tends to be difficult to further reduce the line width of the gate electrode 60 (i.e., a gate length L1) more than the line width that is allowed to be reduced by a general exposure equipment.

### Detailed Memory Cell Operation

A potential difference is generated between the gate electrode 60 and the first LDD layer 13, when a signal configured to switch on/off the memory cell (i.e., transistor) is provided for the gate electrode 60 and a signal configured to make the first charge storage layer 22 store information is provided for the first LDD layer 13 through the diffusion layer 11. Then, as indicated by a dashed arrow shown in FIG. 2, the potential difference generates an electric field E1 that runs from the surface 60b facing the first sidewall 20 to the first LDD layer 13. The electric field E1 causes charges to enter the first charge storage layer 22 from the first LDD layer 13 and/or causes charges to be discharged from the first charge storage layer 22 to the first LDD layer 13. This causes information to be written and/or erased on/from the first sidewall 20.

On the other hand, a potential difference is generated between the gate electrode 60 and the second LDD layer 14, when a signal configured to switch on/off the memory cell (i.e., transistor) is provided for the gate electrode 60 and a signal configured to make the second charge storage layer 32 store information is provided for the second LDD layer 14 through the diffusion layer 12. Then, as indicated by a dashed arrow shown in FIG. 2, the potential difference generates an electric field E2 that runs from the surface 60a facing the second sidewall 30 to the second LDD layer 14. The electric field E2 causes charges to enter the second charge storage layer 32 from the second LDD layer 14 and/or causes charges to be discharged from the second charge storage layer 32 to the second LDD layer 14. This causes information to be written and/or erased on/from the second sidewall 30.

As described above, the memory cell (i.e., transistor) is configured so that information is allowed to be stored in the first sidewall 20 and the second sidewall 30, respectively. Thus, it is configured to store two-bit information per cell.

### Manufacturing Method of Semiconductor Device

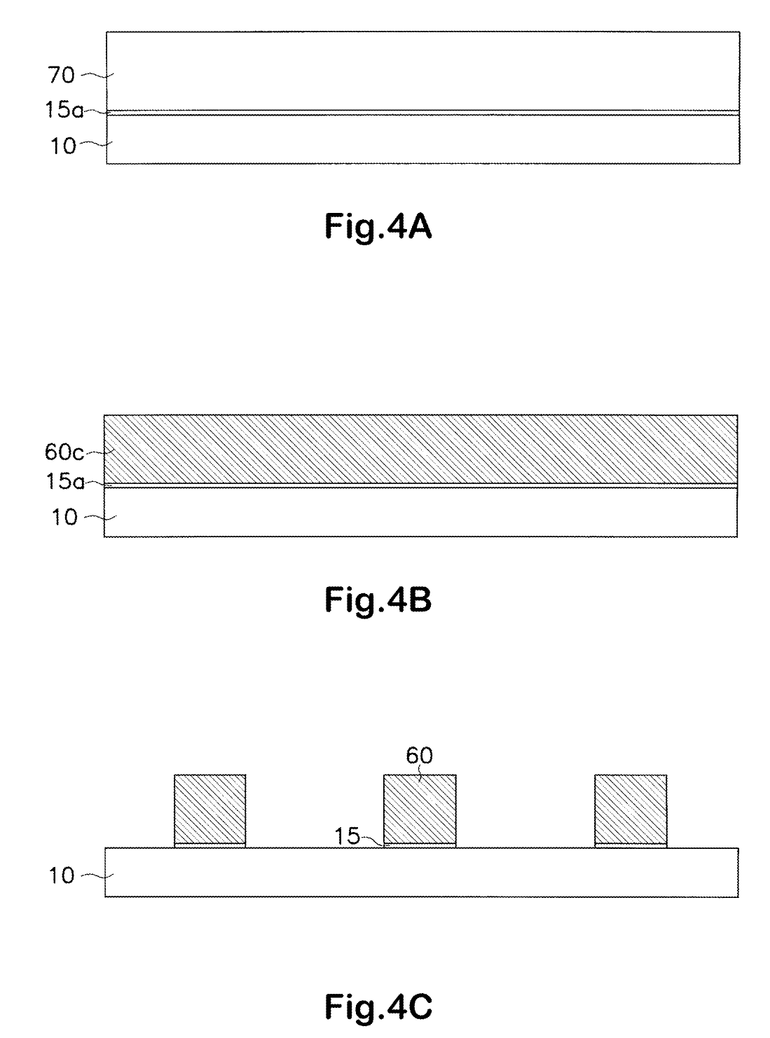

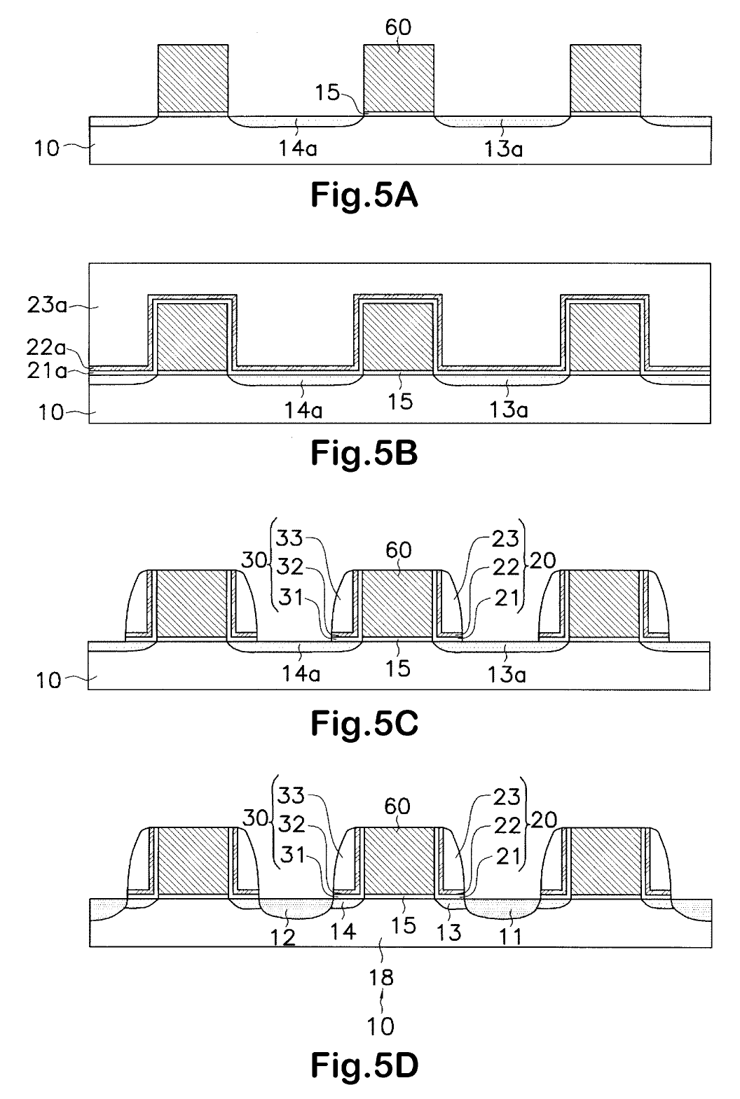

A method configured to manufacture a semiconductor device will be hereinafter explained with reference to cross-sectional views shown in FIGS. 4A to 4C and 5A to 5D.

A semiconductor substrate is prepared in a preparation step S1. More specifically, a silicon substrate 10 is prepared as shown in FIG. 4A. Here, p-type impurities (e.g., p-type ions) are lightly doped in the semiconductor substrate 10 preliminarily. Then, element isolation films 16 and 17 (see FIG. 3) are formed in the semiconductor substrate 10. Thus, the surface of the semiconductor substrate 10 is separated into an active region and a non-active region. Moreover, a gate oxide film 15a is formed on the surface of the active region by means of thermal oxidation or the like, and a sacrifice nitride film 70 is formed by means of the CVD method or the like. Note that only the active region is hereinafter shown in the cross-sectional views for the purpose of clarifying the configuration thereof.

Next, a gate electrode is formed in a gate electrode formation step S2. That is, as shown in FIG. 4B, the sacrifice nitride film 70 is removed by means of dry etching or the like, and a polysilicon layer (i.e., gate electrode 60c) is formed by means of the CVD method or the like. Then, as shown in FIG. 4C, a pattern comprised of the gate electrode 60 and the gate oxide film 15 is formed by means of an exposure process or the like.

Next, an LDD layer is formed in a first implantation step S3. That is, as shown in FIG. 5A, n-type impurity ions (e.g., As ions) are lightly doped into the semiconductor substrate 10 with use of the gate electrode 60 as a mask under conditions in which, for example, the acceleration energy is 30 keV and the dose amount is 1E15 [1/cm²] Thus, a first LDD layer 13a, a second LDD layer 14a, and the like are formed in the semiconductor substrate 10.

Next, a first sidewall, a second sidewall, and the like are formed in a sidewall formation step S4. More specifically, as shown in FIG. 5B, a silicon oxide film (i.e., first insulation layer 21a) with the thickness of 10 nm is formed on the entire surface of the semiconductor substrate 10 with the CVD method or the like. Then, a silicon nitride film (i.e., charge storage film 22a) with the thickness of approximately 8 mm is formed on the entire surface of the first insulation layer 21a with the CVD method or the like. In addition, a silicon oxide film (i.e., third insulation layer 23a) is formed on the entire surface of the charge storage film 22a with the CVD method or the like.

Then, as shown in FIG. 5C, the third insulation layer 23a is etched back by means of dry etching or the like. Thus, portions of the surface of the semiconductor substrate 10 are exposed, and at the same time as this, a first sidewall 20, a second sidewall 30, and the like are formed.

Next, source/drain electrodes (i.e., diffusion layers) are formed in a third implantation step S5. More specifically, as shown in FIG. 5D, n-type impurity ions (e.g., As ions) are heavily doped into the semiconductor substrate 10 with use of the first sidewall 20 and the second sidewall 30 as masks under conditions in which, for example, the acceleration energy is 50 keV and the dose amount is 1E15 [1/cm²] Because of this, diffusion layers 11 and 12, and the like are formed in the semiconductor substrate 10. In addition, a first LDD layer 13 is formed to be located horizontally between the gate electrode 60 and the diffusion layer 11, and a second LDD layer 14 is formed to be located horizontally between the gate electrode 60 and the diffusion layer 12.

### Semiconductor Device of First Embodiment

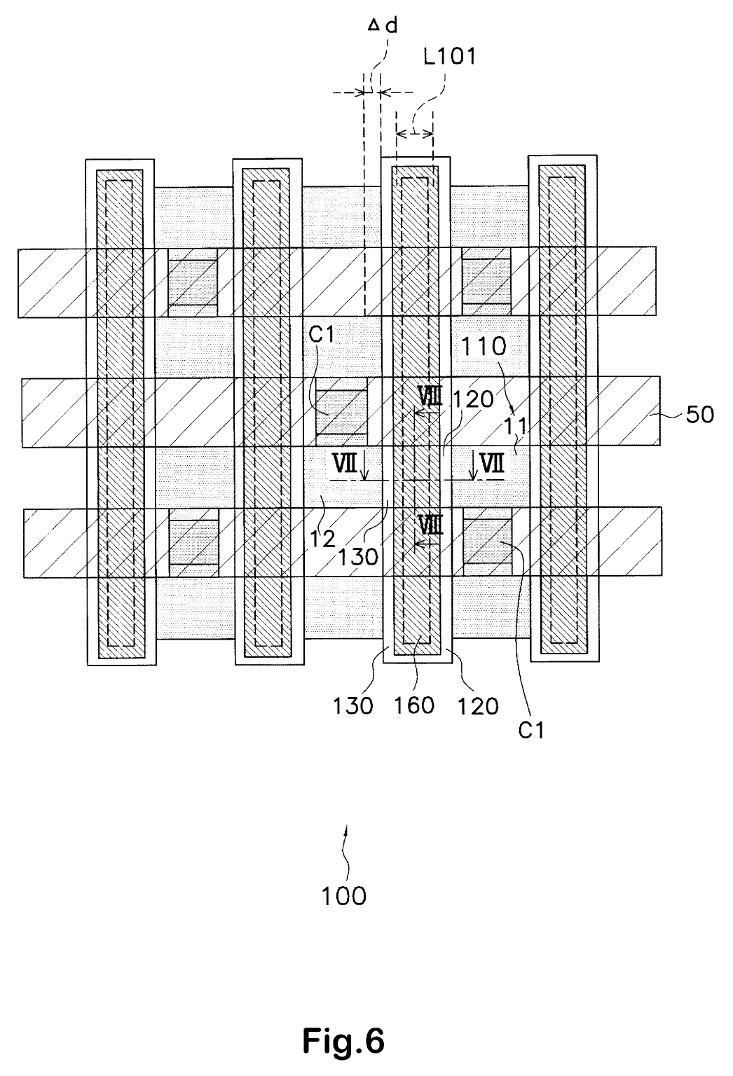

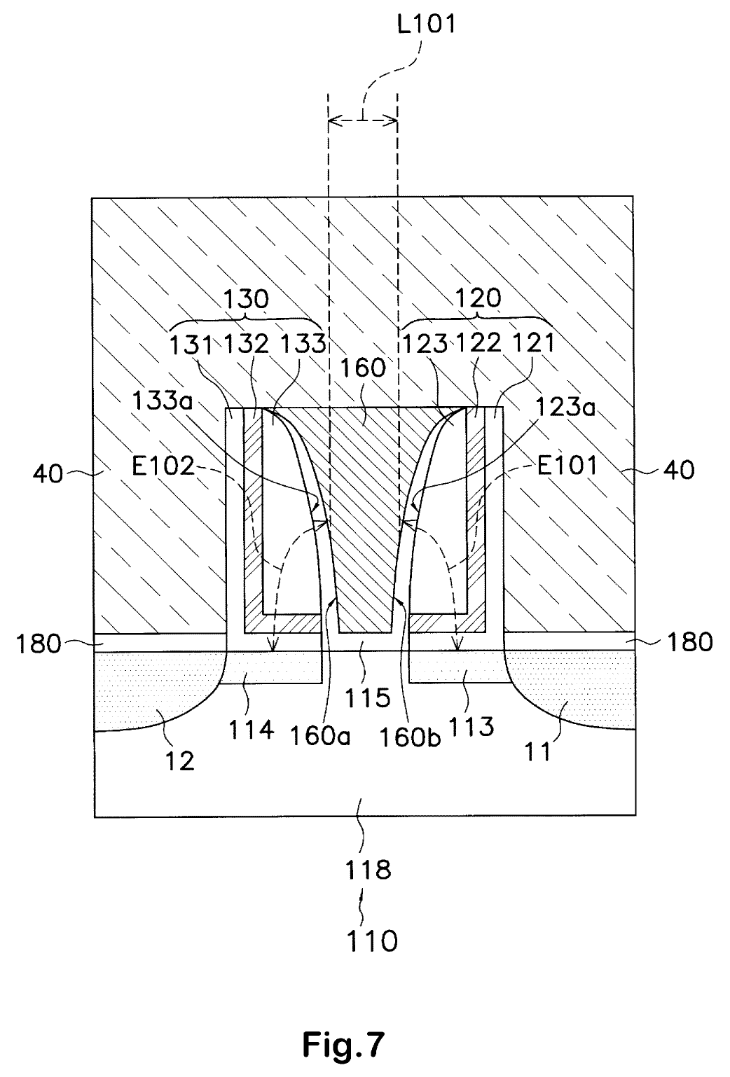

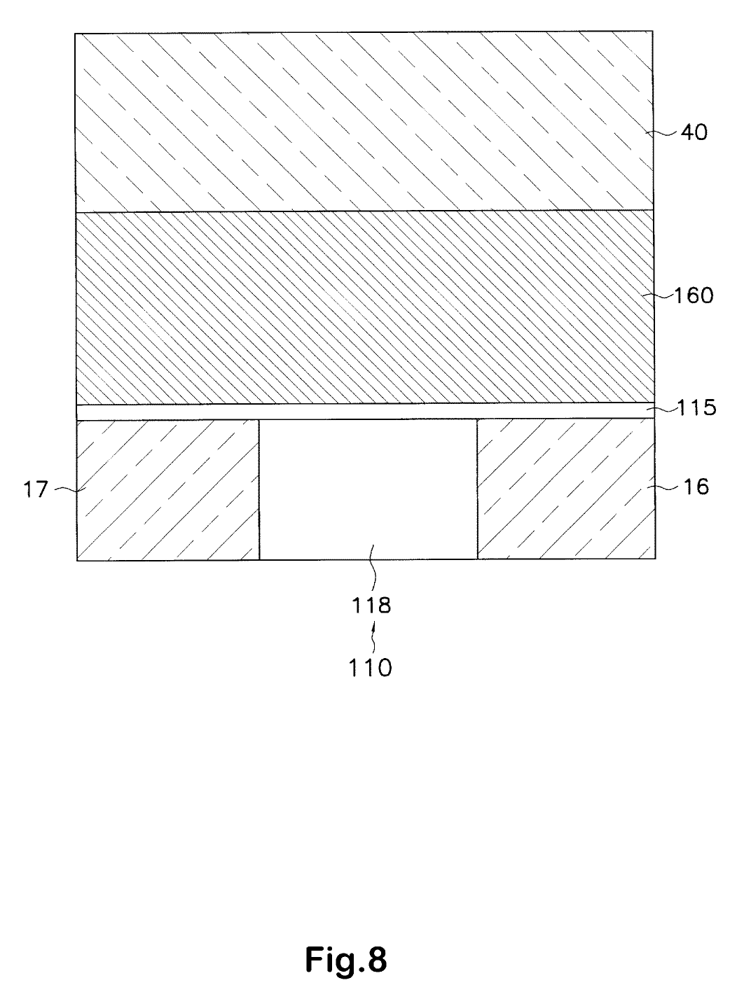

FIG. 6 is a layout of a semiconductor device in accordance with the first embodiment of the present invention. FIG. 7 is a cross-sectional view in a cross section VII-VII of the semiconductor device in accordance with the first embodiment shown in FIG. 6. FIG. 8 is a cross-sectional view in a cross section VIII-VIII of the semiconductor device in accordance with the first embodiment shown in FIG. 6. Note that portions of the semiconductor device in accordance with the first embodiment, which are different from those in the semiconductor device, are mainly hereinafter explained. Also, note that the portions of the semiconductor device in accordance with the first embodiment, which are the same as those in the semiconductor device, are explained with the same numerals, and explanation thereof will be hereinafter omitted.

The basic configuration of a semiconductor device 100 in accordance with the first embodiment is the same as that of the above described semiconductor device. However, they are different from each other in that the semiconductor device 100 includes a semiconductor substrate 110 instead of the semiconductor substrate 10, a gate electrode 160 instead of the gate electrode 60, a first sidewall 120 instead of the first sidewall 20, and a second sidewall 130 instead of the second sidewall 30. As described below, a first LDD layer 113 and a second LDD layer 114 are formed in the semiconductor substrate 110 instead of the first LDD layer 13 and the second LDD layer 14, respectively.

### Detailed Memory Cell Configuration

As shown in FIG. 7, a memory cell (i.e., transistor) includes the gate electrode 160 instead of the gate electrode 60, the first sidewall 120 instead of the first sidewall 20, the second sidewall 130 instead of the second sidewall 30, the first LDD layer 113 instead of the first LDD layer 13, and the second LDD layer 114 instead of the second LDD layer 14.

The first sidewall 120 includes a first insulation layer 121 instead of the first insulation layer 21, a first charge storage layer 122 instead of the first charge storage layer 22, and a third insulation layer 123 instead of the third insulation layer 23. The third insulation layer 123 includes a first sloping surface 123a. The first sloping surface 123a faces the gate electrode 160. The first sloping surface 123a slopes so as to close the gap with the second sidewall 130 as it gets closer to the semiconductor substrate 110.

The second sidewall 130 includes a second insulation layer 131 instead of the second insulation layer 31, a second charge storage layer 132 instead of the second charge storage layer 32, and a fourth insulation layer 133 instead of the fourth insulation layer 33. The fourth insulation layer 133 includes a second sloping surface 133a. The second sloping surface 133a faces the gate electrode 160. The second sloping surface 133a slopes so as to close the gap with the first sidewall 120 as it gets closer to the semiconductor substrate 110.

The gate electrode 160 is formed to include a surface located along the first sloping surface 123a and a surface located along the second sloping surface 133a. More specifically, the gate electrode 160 is configured so that a surface 160b facing the first sidewall 120 is the surface located along the first sloping surface 123a, and a surface 160a facing the second sidewall 130 is the surface located along the first sloping surface 123a. In addition, the gate electrode 160 is formed to have an inverted mesa shape in a cross section thereof that is perpendicular to a longitudinal direction (see FIG. 6) of the first sidewall 120.

Here, it is easy to further reduce the line width of the gate electrode 160 (i.e., a gate length L101) more than the line width that is allowed to be reduced by a general exposure equipment. Note that the gate length L101 indicates an effective line width of the gate electrode 160. In other words, it indicates a line width of a portion of the gate electrode 160 having half the height of the entire gate electrode 160 in a cross section shown in FIG. 7.

In addition, the first LDD layer 113 is formed to be located horizontally between the gate electrode 160 and the diffusion layer 11 in the semiconductor substrate 110 so that the thickness thereof is configured to be constant as the horizontal position thereof is apart from the gate electrode 160.

The second LDD layer 114 is formed to be located between the gate electrode 60 and the diffusion layer 11 in the semiconductor substrate 110 so that the thickness thereof is configured to be constant as the horizontal position thereof is apart from the gate electrode 160.

Other configurations of the semiconductor device 110 in accordance with the first embodiment is the same as those of the above described semiconductor device.

### Detailed Memory Cell Operation

A potential difference is generated between the gate electrode 160 and the first LDD layer 113, when a signal configured to switch on/off the memory cell (i.e., transistor) is provided for the gate electrode 160 and a signal configured to make the first charge storage layer 122 store information is provided for the first LDD layer 113 through the diffusion layer 11. Then, as indicated by a dashed arrow shown in FIG. 7, the potential difference generates an electric field E101 that runs from the surface 160b facing the first sidewall 120 to the first LDD layer 113.

Here, an angle formed by the surface 160b facing the first sidewall 120 and the surface of the first LDD layer 113 is formed to be an acute-angled, while the angle formed by the surface 60b facing the first sidewall 20 and the surface of the first LDD layer 13 is formed to be right-angled (see FIG. 2). With this configuration, it is easier to set the electric field E101 to be larger than the electric field E1.

In addition, the first LDD layer 113 is formed so that thickness thereof will be constant as the horizontal position thereof is apart from the gate electrode 160, while the first LDD layer 13 is formed so that thickness thereof will be gradually larger as the horizontal position thereof is apart from the gate electrode 60. With this configuration, it is further easier to set the electric field E101 to be larger than the electric field E1.

As described above, the speed at which charges are stored in the first charge storage layer 122 will be easily enhanced.

On the other hand, a potential difference is generated between the gate electrode 160 and the second LDD layer 114, when a signal configured to switch on/off the memory cell (i.e., transistor) is provided for the gate electrode 160 and a signal configured to make the second charge storage layer 114 store information is provided for the second LDD layer 114 through the diffusion layer 12. Then, as indicated by a dashed arrow shown in FIG. 7, the potential difference generates an electric field E102 that runs from the surface 160a facing the second sidewall 130 to the second LDD layer 114.

Here, an angle formed by the surface 160a facing the second sidewall 130 and the surface of the second LDD layer 114 is formed to be an acute-angled, while the angle formed by the surface 60a facing the second sidewall 30 and the surface of the second LDD layer 14 is formed to be right-angled (see FIG. 2). With this configuration, it is easier to set the electric field E102 to be larger than the electric field E2.

In addition, the second LDD layer 114 is formed so that thickness thereof will be constant as the horizontal position thereof is apart from the gate electrode 160, while the second LDD layer 14 is formed so that thickness thereof will be larger as the horizontal position thereof is apart from the gate electrode 60. With this configuration, it is further easier to set the electric field E102 to be larger than the electric field E2.

As described above, the speed at which charges are stored in the second charge storage layer 132 will be easily enhanced.

Other configurations of the semiconductor device 110 in accordance with the first embodiment is the same as those of the above described semiconductor device. Manufacturing Method of Semiconductor Device

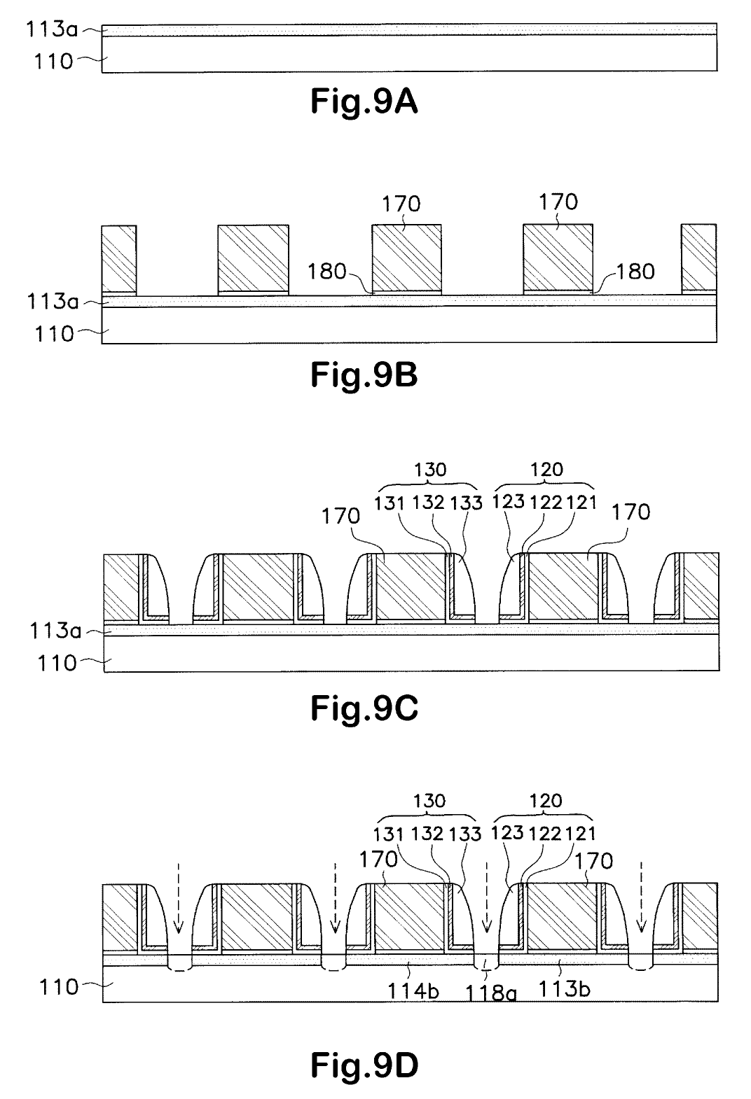

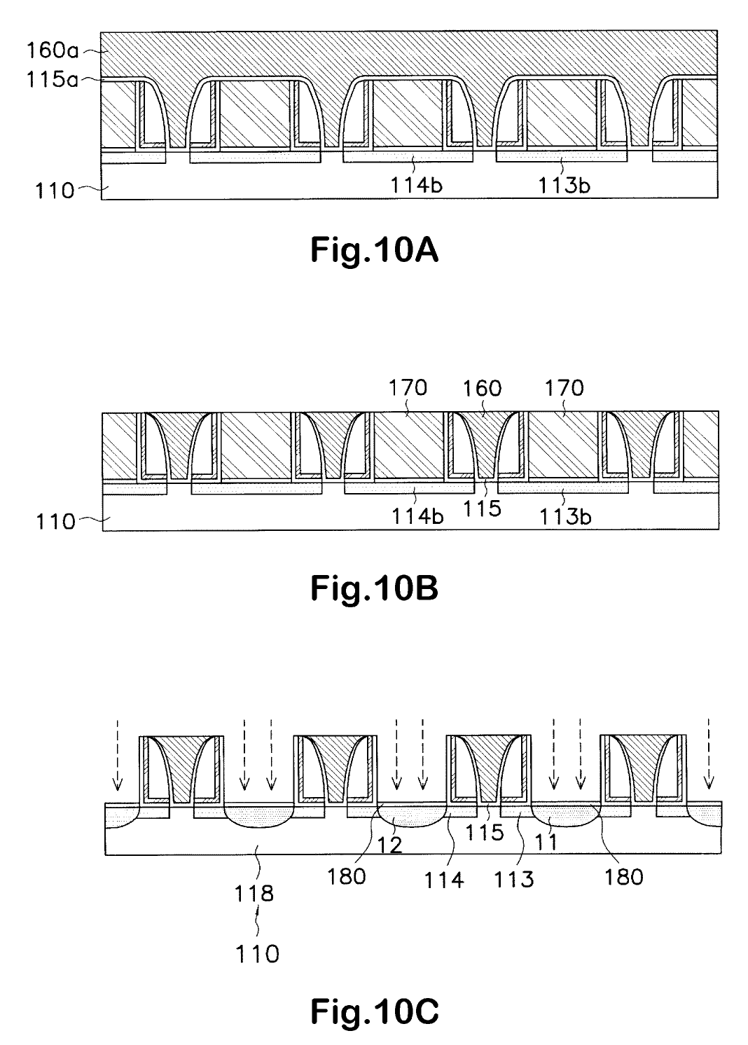

A method configured to manufacture a semiconductor device in accordance with the first embodiment will be hereinafter explained with reference to cross-sectional views shown in FIGS. 9A to 9D and 10A to 10C.

As shown in FIG. 9A, a silicon substrate 110 is prepared instead of the semiconductor substrate 10 in a preparation step S101. Here, a LDD layer 113a is preliminary formed on the entire surface of the semiconductor substrate 110. Then, as shown in FIG. 9B, a sacrifice oxide film 180 with the thickness of 100 Å and a sacrifice nitride film 170 are sequentially formed. Moreover, a pattern comprised of the sacrifice oxide film 180 and the sacrifice nitride film 170 is formed by means of an exposure process, and the surface of the semiconductor substrate 110 is partially exposed through the pattern.

Next, a silicon oxide film (i.e., first insulation layer) is formed on the entire surface of the semiconductor substrate 110 by means of the CVD method or the like in a sidewall formation step S104. Then, a silicon nitride film (i.e., charge storage film) is formed on the first insulation layer by means of the CVD method or the like. Moreover, a silicon oxide film (i.e., third insulation layer) is formed on the charge storage film by means of the CVD method or the like.

Then, as shown in FIG. 9C, the third insulation layer is etched back by means of dry etching or the like. Thus, the surface of the semiconductor substrate 110 is partially exposed, and a first sidewall 120, a second sidewall 130, and the like are formed. Here, the first sidewall 120 and the second sidewall 130 are formed to be arranged side by side in approximately parallel with each other on the semiconductor substrate 110.

Next, a LDD layer is partially separated in a second implantation step S106. More specifically, as shown in FIG. 9D, p-type impurity ions (e.g., B ions) are lightly doped into the semiconductor substrate 110 with use of the first sidewall 120 and the second sidewall 130 as masks under conditions in which, for example, the acceleration energy is 10 keV and the dose amount is 1.5E13 [1/cm²]. With this step, a LDD layer 113a is separated into a plurality of portions. Thus, a first LDD layer 113b, a second LDD layer 114b, and the like are formed.

Next, as shown in FIG. 10A, a gate oxide film 115a is formed by means of the CVD method or the like and then a polysilicon layer (i.e., a gate electrode 160a) is formed by means of the CVD method or the like in a gate electrode formation step S102. Then, as shown in FIG. 10B, the sacrifice nitride film 170 is exposed and at the same time as this, a gate electrode 160 is formed by means of etch back performed by dry etching, planarization performed by chemical mechanical polishing (CMP), and the like. Here, the gate electrode 160 is formed to be located between the first sidewall 120 and the second sidewall 130.

Next, as shown in FIG. 10C, the sacrifice nitride film 170 is removed and the surface of the semiconductor substrate 110 is partially exposed in a third implantation step S1105.

In the first embodiment, the gate electrode formation step S102 is performed after the sidewall formation step S104, while the sidewall formation step S104 is performed after the gate electrode formation step S2. In other words, the order of performing the gate electrode formation step and the sidewall formation step is different between the manufacturing method of the semiconductor device and that of the semiconductor device in accordance with the first embodiment. Accordingly, the gate electrode 160 is formed to be located between the first sidewall 120 and the second sidewall 130.

In addition, the second implantation step S106 is added to be performed after the sidewall formation step S104 and before the gate electrode formation step S102 in the manufacturing method of the semiconductor device in accordance with the first embodiment, compared to the manufacturing method of the semiconductor device. This enables counter-doping to be performed with respect to the LDD layer 113a with use of the first sidewall 120 and the second sidewall 130 as masks. Accordingly, the first LDD layer 113 and the second LDD layer 114 are configured to be formed, even if the gate electrode 160 is formed after the first sidewall 120 and the second sidewall 130 are formed.

Note that the first implantation step S3 performed in the manufacturing method of the semiconductor device is not necessary for the manufacturing method of the semiconductor device in accordance with the first embodiment because the LDD layer 113a is preliminary formed in the preparation step S101.

As described above, the number of steps required for the manufacturing method of the semiconductor device in accordance with the first embodiment is the same as that required for the manufacturing method of the semiconductor device.

Other configurations of the semiconductor device in accordance with the first embodiment is the same as those of the above described semiconductor device.

### Features of Semiconductor Device

First, the gate electrode 160 is formed to include a surface located along the first sloping surface 123a and a surface located along the second sloping surface 133a. With this configuration, it is easy to further reduce the gate length L101 more than the gate length that is allowed to be reduced by conventional exposure equipment.

As described above, it is easy to further reduce the gate length L101 more than the gate length that is allowed to be reduced by conventional exposure equipment. Accordingly, it is possible to inhibit cost increase and reduce the cell size.

Second, the first charge storage layer 122 stores charges in the first embodiment. The first insulation layer 121 is formed between the semiconductor substrate 110 and the first charge storage layer 122. With this configuration, the semiconductor substrate 110 and the first charge storage layer 122 are configured to be electrically isolated from each other. Accordingly, the first charge storage layer 122 is configured to retain charges.

In addition, the second charge storage layer 132 stores charges in the first embodiment. The second insulation layer 131 is formed to be located between the semiconductor substrate 110 and the second charge storage layer 132. With this configuration, the semiconductor substrate 110 and the first charge storage layer 132 are configured to be electrically isolated from each other. Accordingly, the second charge storage layer 132 is configured to retain charges.

Third, the third insulation layer 123 includes a first sloping surface 123a in the first embodiment. In addition, the fourth insulation layer 133 includes a second sloping surface 133a. With these configurations, the gate electrode 160 is configured so that the surface 160b facing the first sidewall 120 is a surface located along the first sloping surface 123a, and the surface 160a facing the second sidewall 130 is a surface located along the first sloping surface 133a. In other words, the gate electrode 160 is formed to include the surface located along the first sloping surface 123a and the surface located along the second sloping surface 133a.

Fourth, the gate electrode 160 is formed to have an inverted mesa shape in a cross section thereof that is perpendicular to a longitudinal direction of the first sidewall 120 in the first embodiment. With this configuration, the gate electrode 160 is formed to include a surface located along the first sloping surface 123a and a surface located along the second sloping surface 133a.

In addition, the electric field E101 (or the electric field E102) is configured to be effectively generated in the first sidewall 120 (or second sidewall 130) through a surface located along the first sloping surface 123a (or a surface located along the second sloping surface 133a). Accordingly, the speed at which charges are stored in the first charge storage layer 122 (or the second charge storage layer 132) will be easily enhanced.

### Features of Manufacturing Method of Semiconductor Device

Fifth, the gate electrode formation step S102 is performed after the sidewall formation step S104 in the first embodiment, while the sidewall formation step S4 is performed after the gate electrode formation step S2 in the manufacturing method of the semiconductor device. In other words, the order of performing the gate electrode formation step and the sidewall formation step is different between the manufacturing method of the semiconductor device in accordance with the first embodiment and that of the semiconductor device. Accordingly, the gate electrode 160 is formed to be located between the first sidewall 120 and the second sidewall 130. In other words, the gate electrode 160 is formed to include a surface located along the first sloping surface 123a and a surface located along the second sloping surface 133a. Because of this, the gate electrode 160 is formed so that the gate length L101 is further reduced more than the gate length that is allowed to be reduced by conventional exposure equipment.

As described above, the gate electrode 160 is formed so that the gate length L101 is further reduced more than the gate length that is allowed to be reduced by conventional exposure equipment. Accordingly, it is possible to inhibit cost increase and reduce the cell size.

Sixth, the second implantation step S106 is performed after the sidewall formation step S104 and before the gate electrode formation step S102 in the first embodiment. This enables counter-doping to be performed with respect to the LDD layer 113a with use of the first sidewall 120 and the second sidewall 130 as masks. Accordingly, the first LDD layer 113 and the second LDD layer 114 are configured to be formed even if the gate electrode 160 is formed after the first sidewall 120 and the second sidewall 130 are formed.

### Alternative of First Embodiment

The gate electrode 160 may include a plurality of layers such as a polysilicon layer, a tungsten silicide layer, and the like, instead of only the polysilicon layer. In this configuration, the tungsten silicide layer and the like are laminated on the polysilicon layer.

### Semiconductor Device of Second Embodiment

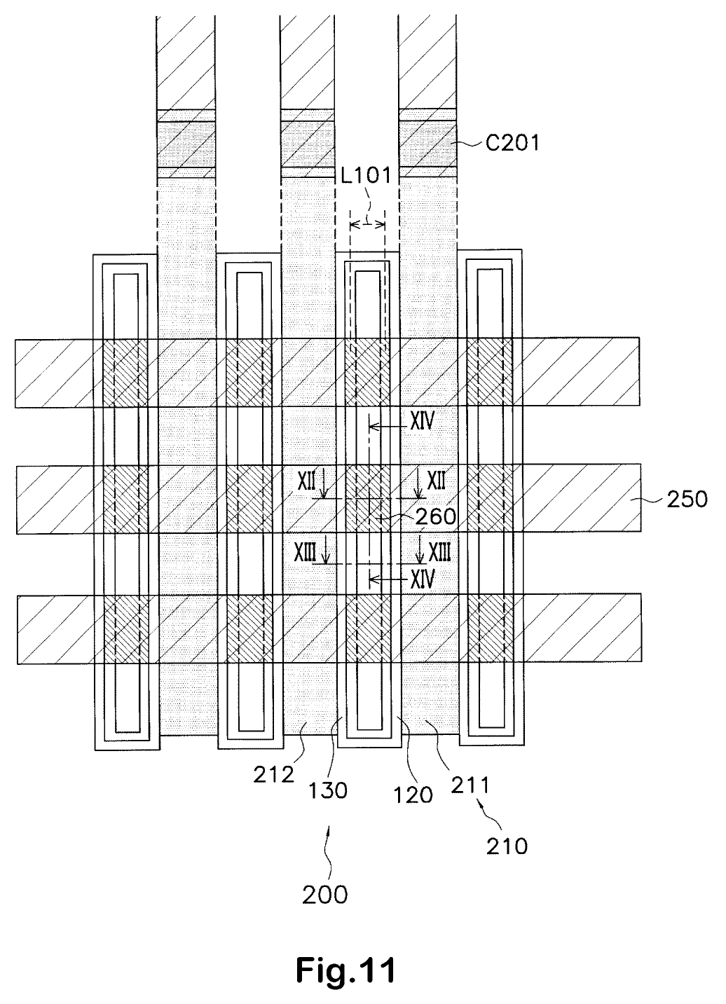

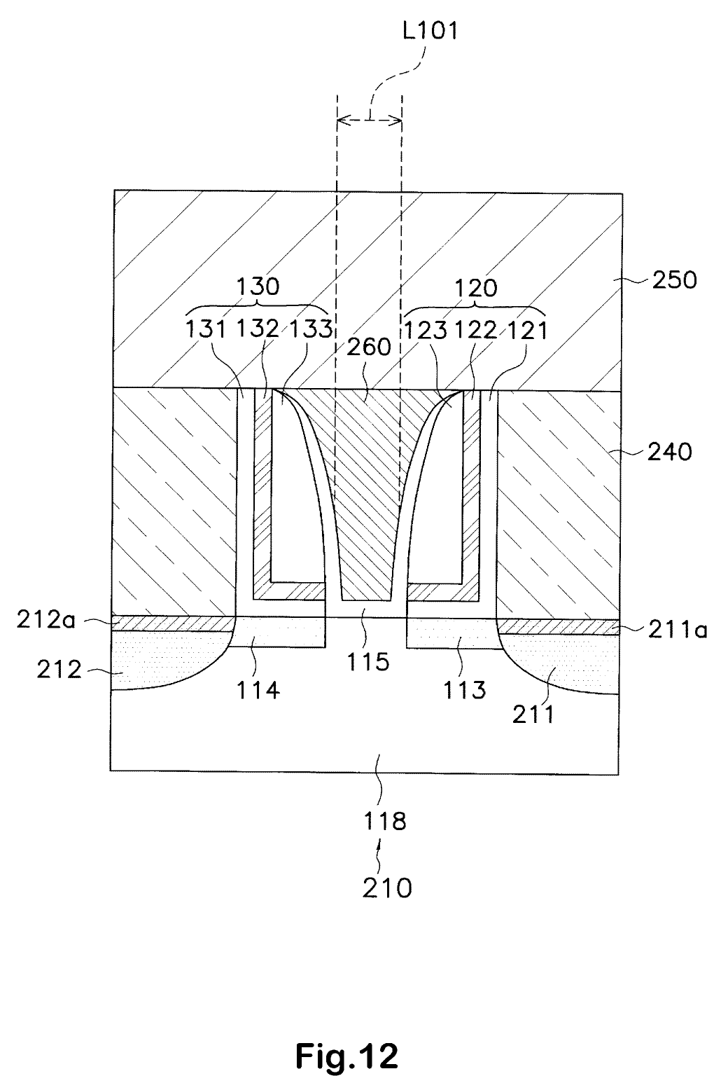

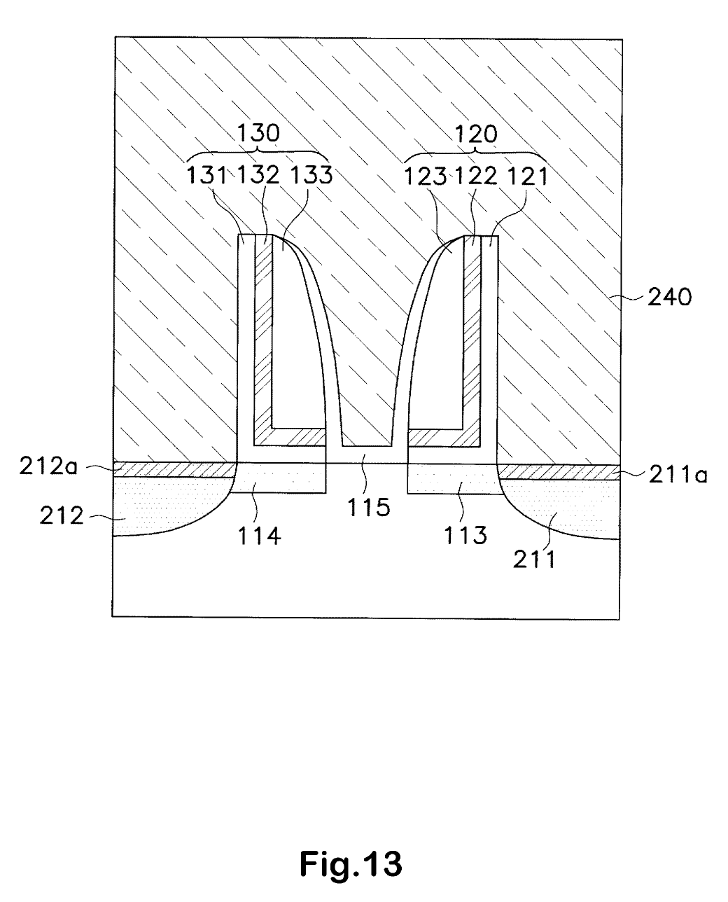

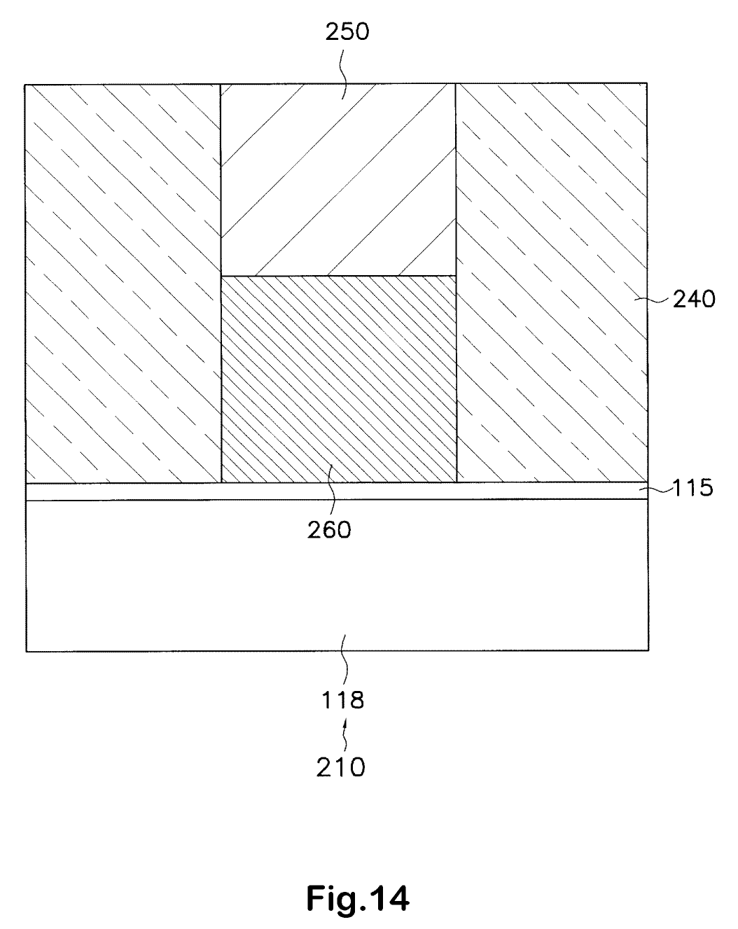

FIG. 11 is a layout of a semiconductor device in accordance with the second embodiment of the present invention. FIG. 12 is a cross-sectional view in a cross section XII-XII of the semiconductor device in accordance with the second embodiment shown in FIG. 11. FIG. 13 is a cross-sectional view in a cross section XIII-XIII of the semiconductor device in accordance with the second embodiment shown in FIG. 11. FIG. 14 is a cross-sectional view in a cross section XIV-XIV of the semiconductor device in accordance with the second embodiment shown in FIG. 11. Note that the portions of the semiconductor device in accordance with the second embodiment of the present invention which are different from those in the semiconductor device and the semiconductor device in accordance with the first embodiment will be hereinafter mainly explained. Also, note that the portions of the semiconductor device in accordance with the second embodiment which are the same as those in the semiconductor device and the semiconductor device in accordance with the first embodiment will be explained with the same numerals, and explanation thereof will be hereinafter omitted.

The basic configuration of a semiconductor device 200 in accordance with the second embodiment is the same as that of the above described semiconductor device and that of the semiconductor device in accordance with the first embodiment. However, the semiconductor device 200 and the above described semiconductor devices are different in that the semiconductor device 200 includes a semiconductor substrate 210 instead of the semiconductor substrate 10, a gate electrode 260 instead of the gate electrode 60, and a wiring layer 250 instead of the wiring layer 50.

Diffusion layers 211 and 212 are formed in the semiconductor substrate 210 instead of the diffusion layers 11 and 12. The diffusion layers 211 and 212 function as source and drain electrodes of a memory cell (i.e., transistor) and at the same as this, function as bit lines. In addition, they are configured so that a signal configured to make a first sidewall 120 and/or a second sidewall 130 store(s) information (i.e., charges) therein is allowed to be input into the diffusion layers 211 and 121 through contacts C201.

The gate electrodes 260 are formed on the semiconductor device 210 in a scattered island shape. More specifically, the gate electrodes 260 (see FIGS. 12 to 14) correspond to portions of the gate electrodes 160 (see FIG. 6) remaining after portions of the gate electrodes 160 in which no the wiring layer 250 is formed are removed from the gate electrodes 160.

The wiring layer 250 is formed to be located immediately above the gate electrode 260 without interposing the interlayer film 240 between them. In other words, the gate electrode 260 and the wiring layer 250 function as a word line. Thus, they are configured so that a signal for switching on/off the memory cell (i.e., transistor) can be input therein. Accordingly, resistance of a wiring (i.e., word line) is reduced in the second embodiment, compared to a case in which a bit line is formed only by the gate electrode 160 (see FIG. 6).

The contacts C201 are formed to be located in a peripheral circuit region of the memory cell in the second embodiment. Accordingly, a predetermined space Δd or greater may not be formed between the contact C201 and the first sidewall 120 (or the second sidewall 130). With this configuration, the cell size is allowed to be reduced by locating adjacent gate electrodes 260 closer to each other.

### Detailed Memory Cell Configuration

As shown in FIG. 12, a memory cell (i.e., transistor) includes the gate electrode 260 instead of the gate electrode 60, and the source and drain electrodes (i.e., diffusion layers 211 and 212) instead of the source and drain electrodes (i.e., diffusion layers 11 and 12).

The gate electrode 260 is formed to be coupled to the wiring layer 250.

The diffusion layer 211 includes a cobalt silicide layer 211a in the vicinity of the surface thereof. With this configuration, electric resistance is reduced that is generated when a signal is input into the diffusion layer 211 through the contact C201.

The diffusion layer 212 includes a cobalt silicide layer 212a in the vicinity of the surface thereof. With this configuration, electric resistance is reduced that is generated when a signal is input into the diffusion layer 212 through the contact C201.

Other configurations of the semiconductor device in accordance with the second embodiment is the same as those of the above described semiconductor device and the semiconductor device in accordance with the first embodiment.

### Manufacturing Method of Semiconductor Device

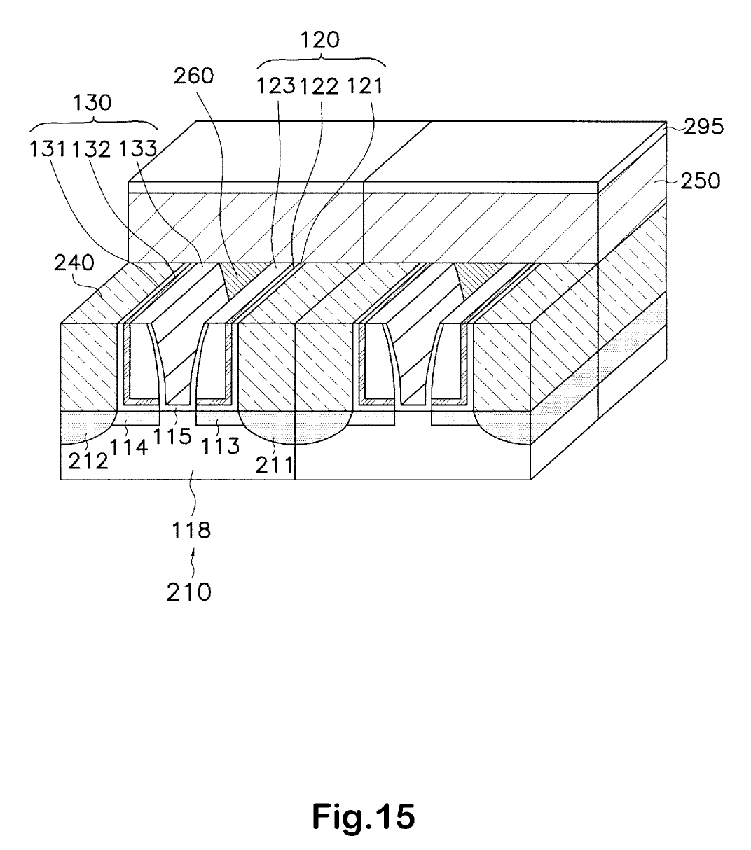

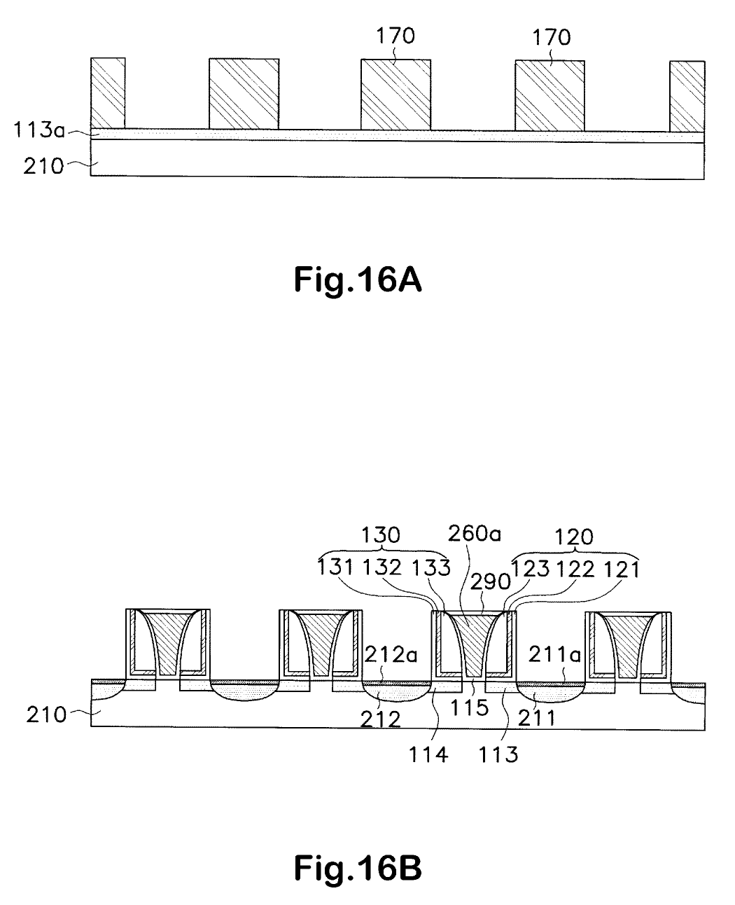

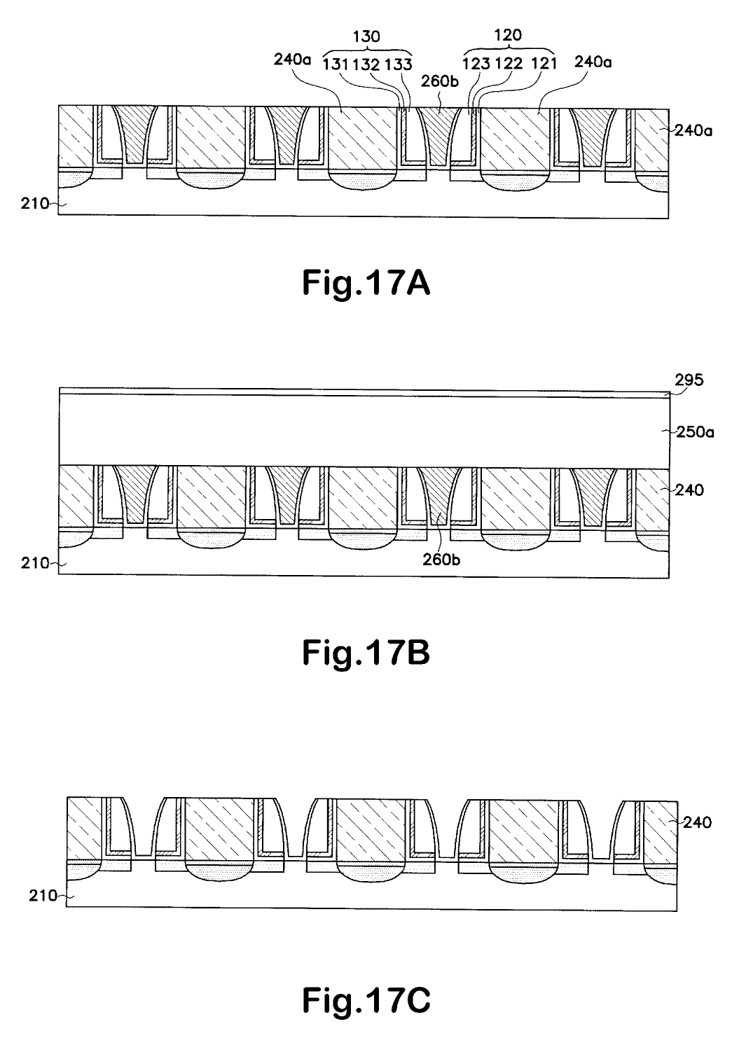

A method configured to manufacture a semiconductor device in accordance with the second embodiment will be hereinafter explained with reference to cross-sectional views shown in FIGS. 16A and 16B and 17A to 17C and a cross-sectional perspective view shown in FIG. 15.

As shown in FIG. 16A, a sacrifice nitride film 170 is formed in a preparation step S201, while a sacrifice oxide film 180 is not formed.

A sidewall formation step, a first implantation step, and a second implantation step performed in the method configured to manufacture the semiconductor device in accordance with the second embodiment are the same as the steps S104, S105, and S106 performed in the method configured to manufacture the semiconductor device in accordance with the first embodiment.

Next, as shown in FIG. 16B, a salicide protection oxide film 290 is formed on the gate electrode 260a with use of the sacrifice nitride film 170 as a mask before the sacrifice nitride film 170 is removed in a third implantation step S205.

Next, a cobalt silicide layer is formed in a metal layer formation step S206.

More specifically, a cobalt layer is formed on the entire surface of the semiconductor substrate 210, and then thermal treatment is performed with respect to the cobalt layer at a low temperature (e.g., 500 degrees Celsius). Thus, the cobalt layer is silicided. Accordingly, as shown in FIG. 16B, cobalt silicide layers 211a and 212a are formed.

Next, an interlayer film is formed in an interlayer film formation step S207. More specifically, a silicon oxide film is formed on the entire surface of the semiconductor substrate 210 by means of the CVD method or the like. Then, as shown in FIG. 17A, gate electrodes 260b are exposed by means of etch back performed by dry etching, planarization performed by CMP, and the like.

Next, a wiring layer is formed in a wiring layer formation step S208. More specifically, as shown in FIG. 17B, a wiring layer 250a is formed on the entire surface of the semiconductor substrate 210, for instance, the upper surface of the gate electrode 260b by means of the CVD method or the like.

Next, a hard mask layer is formed in a hard mask layer formation step S209. More specifically, as shown in FIG. 17B, a silicon oxide film functioning as a hard mask layer 295 is formed immediately above the wiring layer 250a by means of the CVD method or the like.

Next, a pattern comprised of a hard mask layer is formed in a pattern formation step S210. More specifically, a pattern that is approximately the same as the pattern comprised of the wiring layer 250 (see FIG. 11) is formed with respect to the hard mask layer 295 by means of an exposure process.

Next, a pattern comprised of a gate electrode is formed in a gate etching process S211. More specifically, as shown in FIG. 15, the wiring layer 250a and the gate electrode 260b are etched with use of the hard mask layer 295 as an etching stopper by means of dry etching or the like. Thus, a pattern comprised of the wiring layer 250 is formed with use of the hard mask layer 295 in which a pattern is formed as a mask, and at the same time as this, portions of the gate electrodes 260a which are not covered with the wiring layer 250 are etched (see FIG. 17C). Accordingly, a pattern comprised of the gate electrode 260 is formed on the semiconductor device 210 in a scattered island shape.

The gate electrode 260a is formed to have an inverted mesa shape in a cross section thereof that is perpendicular to a longitudinal direction of the first sidewall 120 in the second embodiment. In other words, the gate electrode 260a is formed to have a shape in which poly filament tends not to remain when partially etched.

### Features of Semiconductor Device

In the second embodiment, it is easy to further reduced the gate length L101 more than the gate length that is allowed to be reduced by conventional exposure equipment. This feature is the same as that of the first embodiment. Therefore, with the semiconductor device 200, it is also possible to inhibit cost increase and reduce the cell size.

In addition, the gate electrode 260 and the wiring layer 250 function as a word line. Thus, they are configured so that a signal configured to switch on/off the memory cell (i.e., transistor) is allowed to be input therein. Accordingly, resistance of a wiring (i.e., word line) is reduced in the second embodiment, compared to a case in which a bit line is formed only using the gate electrode 160 (see FIG. 6).

Furthermore, the contacts C201 are formed to be located in a peripheral circuit region in a memory cell. Accordingly, a predetermined space Δd or greater is not configured to be formed between the contact C201 and the first sidewall 120 (or the second sidewall 130). With this configuration, the cell size is allowed to be reduced by locating adjacent gate electrodes 260 closer to each other.

### Features of Manufacturing Method of Semiconductor Device

A pattern comprised of the wiring layer 250 is formed with use of the hard mask layer 295 in which a pattern is formed as a mask, and portions of the gate electrode 260a that are not covered with the wiring layer 250 are etched (see FIG. 17C). Accordingly, a pattern comprised of the gate electrodes 260 is formed on the semiconductor substrate 210 in a scattered island shape.

In addition, the gate electrode 260a is formed to have an inverted mesa shape in a cross section thereof that is perpendicular to a longitudinal direction of the first sidewall 120. In other words, the gate electrode 260a is formed to have a shape in which poly filament tends not to remain when partially etched.

The semiconductor device in accordance with the present invention and the method configured to manufacture the same are useful because they have the effect of inhibiting cost increase and reducing the cell size.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applied to words having similar meanings such as the terms, “including,” “having,” and their derivatives. Also, the term “part,” “section,” “portion,” “member,” or “element” when used in the singular can have the dual meaning of a single part or a plurality of parts. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor device, comprising:
a semiconductor substrate;
a gate electrode disposed above the semiconductor substrate, the gate electrode comprising a surface disposed along a first sloping surface of a first sidewall and a surface disposed along a second sloping surface of a second sidewall;
the first sidewall disposed above the semiconductor substrate to be adjacent to the gate electrode, the first sidewall comprising the first sloping surface, the first sloping surface sloping toward the second sidewall as the first sidewall approaches the semiconductor substrate;
the second sidewall disposed above the semiconductor substrate to face the first sidewall across the gate electrode, the second sidewall comprising the second sloping surface, the second sloping surface sloping toward the first sidewall as the second sidewall approaches the semiconductor substrate.

2. The semiconductor device according to claim 1,
wherein the first sidewall comprises a first charge storage layer configured to store charges and a first insulation layer disposed between the semiconductor substrate and the first charge storage layer, and
the second sidewall comprises a second charge storage layer configured to store charges and a second insulation layer disposed between the semiconductor substrate and the second charge storage layer.

3. The semiconductor device according to claim 2, wherein the first sidewall comprises the first sloping surface and a third insulation layer disposed to face the first insulation layer across the first charge storage layer, and
the second sidewall comprises a second sloping surface and a fourth insulation layer disposed to face the second insulation layer across the second charge storage layer.

4. The semiconductor device according to claim 1, wherein the gate electrode is formed to have an inverted mesa shape in a cross section thereof perpendicular to a longitudinal direction of the first sidewall.

5. The semiconductor device according to claim 2, wherein the gate electrode is formed to have an inverted mesa shape in a cross section thereof perpendicular to a longitudinal direction of the first sidewall.

6. The semiconductor device according to claim 3, wherein the gate electrode is formed to have an inverted mesa shape in a cross section thereof perpendicular to a longitudinal direction of the first sidewall.
